(19) United States
(12) Patent Application Publication
(10) Pub. No.: US 2003/0107035 A1
(43) Pub. Date: Jun. 12, 2003

(54) Semiconductor chip

(75) Inventor: Masatoshi Maga, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/161,807

(22) Filed: Jun. 5, 2002

(30) Foreign Application Priority Data
Dec. 11, 2001 (JP) 2001-377470

(51) Int. Cl. H01L 23/58

(52) U.S. Cl. 257/48

(57) ABSTRACT

Each of a plurality of semiconductor chips comprises an integrated circuit region and a plurality of electrodes for electrical connection to outside. The electrodes are disposed on a surface of each of the semiconductor chips in a predetermined pattern. A distance between a left side of each of the semiconductor chips and each of the electrodes, and a distance between a right side of each of said semiconductor chips and each of the electrodes are predetermined distances, respectively.

### BACKGROUND OF THE INVENTION

1. Field of the Invention

The present invention relates to a semiconductor chip. More specifically, the present invention relates to a semiconductor chip for which the electrical test is conducted using a probe card.

2. Background Art

FIG. 6 is a top view showing a conventional wafer, and semiconductor chips formed on the wafer. FIG. 6A is a diagram showing a wafer, and FIGS. 6B and 6C are diagrams showing semiconductor chips.

FIG. 6B shows two semiconductor chips 80 of the same size adjacent to each other among a plurality of semiconductor chips formed on a wafer 200. On each of the semiconductor chips 80, a plurality of bonding pads 2, which are electrodes for electrically connecting external electrodes (not shown) with an integrated circuit region 4, are provided. The same numbers of bonding pads 2 are disposed on the surface of each semiconductor chip 80 so as to form a quadrangle of the same size.

FIG. 6C shows two semiconductor chips 90 adjacent to each other formed on the different areas from the areas on which the semiconductor chips 80 are formed, among a plurality of semiconductor chips formed on a wafer 200. On the surface of each of the semiconductor chips 90, the same numbers of bonding pads 2 as the number of bonding pads 2 formed on the surface of each semiconductor chip 80 are disposed so as to form a quadrangle of the same size. Each of the semiconductor chips 90 comprises an external integrated circuit region 6 outside the quadrangle formed by the bonding pads 2. Therefore, when the total areas of these semiconductor chips are compared, the semiconductor chip 90 is larger than the semiconductor chip 80.

FIG. 7 is a diagram showing the state where the test of a semiconductor chip 80 is conducted using a probe card.

As FIG. 7 shows, the probe card 10 comprises a plurality of probe needles 8. This test is conducted by allowing each of the probe needles 8 to contact a corresponding bonding pad 2 to make electrical junction, in order to test whether the semiconductor chip operates properly. This probe card 10 is constituted so as to test two semiconductor chips 80 adjacent to each other at the same time. Therefore the probe needles 8 are disposed on the locations corresponding to the locations of the bonding pads 2 so that the tips of the probe needles 8 can contact all the bonding pads 2 formed on the surface on the two semiconductor chips 80 at the same time.

Concurrent with the diversification and increase in the types of semiconductors in recent years, various types of semiconductor chips of different sizes have been formed on a single wafer or between a plurality of wafers.

As described above, in semiconductor chips 80 and 90, the arrangement of all the bonding pads 2 is standardized in the same pattern. However, in the portions between two adjoining semiconductor chips 80 or 90, the distance d₈₀ between two facing sides of quadrangles formed by the bonding pads 2 differs from the distance d₉₀ between two facing sides in the semiconductor chip 90. In such a case, therefore, as FIG. 7 shows, the probe card 10 for testing two semiconductor chips 80 at the same time cannot be used for the semiconductor chip 90 as it is.

In such a case, if the probe card is changed each time the different size or shape of semiconductor chips are changed, problems of increase in operating time due to increase in the number of steps for changing the probe cards, or increase in production costs due to the manufacture of probe cards to meet the size and shape of semiconductor chips arise.

On the other hand, in semiconductor chips 80 and 90, the number and arrangement of quadrangles formed by the bonding pads 2 are standardized to form identical quadrangles. In such a case, tests can be conducted continuously using a probe card having probe needles that meet the arrangement of a quadrangle formed by the bonding pads 2. However, using such a probe card, semiconductor chips must be tested one at a time, and the operating time increases compared with the case where a plurality of semiconductor chips are tested at the same time.

### SUMMARY OF THE INVENTION

Therefore, the present invention aims at the solution of the above-described problems, and proposes the application of a probe card that can test a plurality of semiconductor chips at the same time also to semiconductor chips of different sizes for continuous operation.

According to one aspect of the invention, a plurality of semiconductor chips, each comprises a plurality of electrodes for electrical connection to outside. The electrodes are disposed on a surface of each of the semiconductor chips in a predetermined pattern. A distance between a predetermined side of each of the semiconductor chips and each of the electrodes, and a distance between a side that faces the predetermined side of each of the semiconductor chips and each of the electrodes are predetermined distances, respectively. Accordingly, continuous tests can be conducted using a probe card that can test a plurality of semiconductor chips at the same time, also for other semiconductor chips.

According to another aspect of the present invention, a plurality of semiconductor chips, each comprises a plurality of electrodes for electrical connection to outside. The electrodes are disposed on a surface of each of the semiconductor chips in a predetermined pattern. In a relation between the semiconductor chips adjacent to each other at a predetermined location, a distance between the electrodes facing each other is a predetermined distance. Accordingly, continuous tests can be conducted using a probe card that can test a plurality of semiconductor chips at the same time, also for other semiconductor chips.

Other and further objects, features and advantages of the invention will appear more fully from the following description.

### BRIEF DESCRIPTION OF THE DRAWINGS

FIG. 1A to FIG. 1C are top views showing a wafer and semiconductor chips in First Embodiment of the present invention;

FIG. 2 is a diagram showing a probe card used in First Embodiment of the present invention;

FIG. 3A and FIG. 3B are conceptual diagrams showing the state of the test of semiconductor chips using a probe card;

FIG. 4A and FIG. 4B are top views showing a semiconductor chip according to Third Embodiment of the present invention;

FIG. 5A and FIG. 5B are diagrams showing semiconductor chips to be tested according to Fourth Embodiment of the present invention;

FIG. 6A to FIG. 6C are top views showing a conventional wafer, and semiconductor chips formed on the wafer;

FIG. 7 is a diagram showing the state where the test of a semiconductor chip is conducted using a probe card;

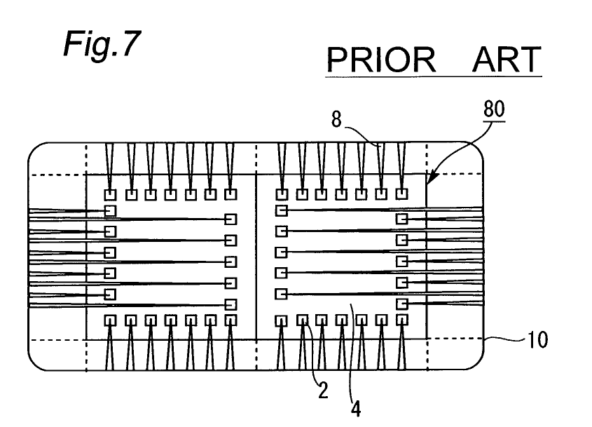

### DETAILED DESCRIPTION OF THE PREFERRED EMBODIMENTS

The embodiments of the present invention will be described below referring to the drawings. In the drawings, the same or corresponding portions will be denoted by the same reference numerals, and the description of such portions will be simplified or omitted.

First Embodiment

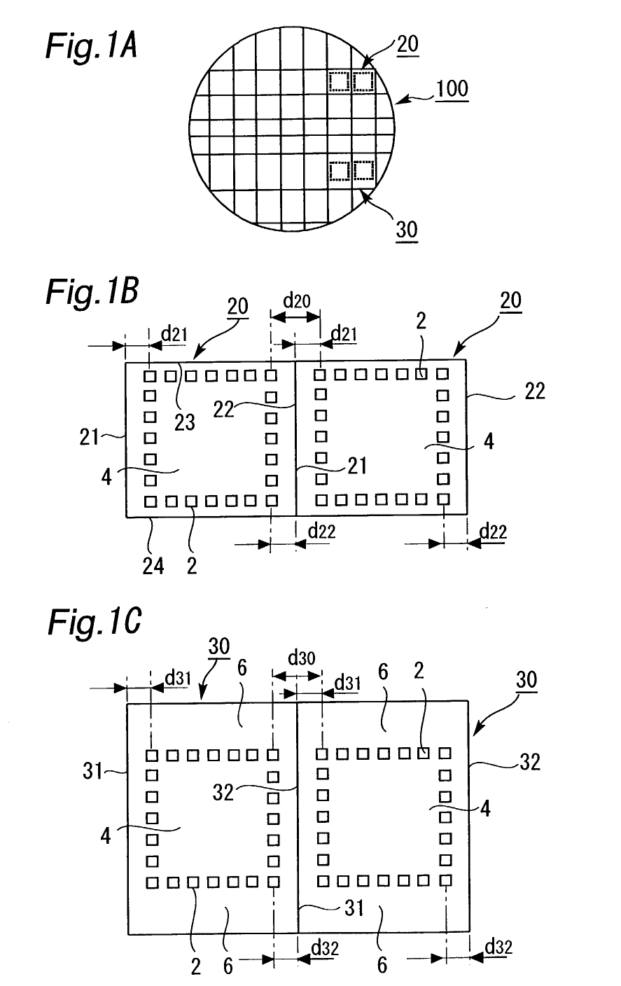

FIG. 1 is a top view showing a wafer and semiconductor chips in First Embodiment of the present invention. FIG. 1A shows a wafer, and FIGS. 1B and 1C show semiconductor chips.

In FIG. 1A, the reference numeral 100 denotes a wafer, and reference numerals 20 and 30 show semiconductor chips. The semiconductor chips 20 and 30 are semiconductor chips of different sizes and shapes formed on the different portions of a wafer 100. Thus, a plurality of semiconductor chips of different sizes and shapes are formed on the wafer 100.

FIG. 1B and FIG. 1C show two adjoining semiconductor chips 20 and 30 of the same size formed on the wafer 100, respectively.

In FIG. 1B, the reference numeral 2 denotes a bonding pad, and the reference numeral 4 denotes an integrated circuit region. The bonding pad 2 is an electrode for connecting the integrated circuit region 4 on which a circuit function is formed with an external electrode. On the surface of each of the semiconductor chips 20, the same numbers of bonding pads 2 are disposed so as to form the same size of quadrangle. The upper sides and the lower sides of the quadrangles on adjoining semiconductor chips 20 are in line with each other, respectively. The integrated circuit region 4 is disposed on the internal area of the quadrangularly arranged bonding pads 2.

Referring FIG. 1C, on the surface of each semiconductor chip 30, the same number of bonding pads 2 as the number of bonding pads 2 formed on the surface of the semiconductor chip 20 are arranged so as to form a quadrangle of the same size as the quadrangle formed by the bonding pads 2 on the surface of the semiconductor chip 20. Similar to the semiconductor chip 20, the upper sides and the lower sides of the quadrangles on adjoining semiconductor chips 30 are in line with each other, respectively. Also, the integrated circuit region 4 is disposed on the internal area of the quadrangularly arranged bonding pads 2.

The reference numeral 6 denotes an external integrated circuit region. The external integrated circuit regions 6 are formed on the upper and lower areas of the areas outside the quadrangle formed by the bonding pad 2 on the surface of the semiconductor chip 30.

Since the semiconductor chip 30 has external integrated circuit regions 6 formed on the upper and lower areas, the lengthwise width is larger than the length width of the semiconductor chip 20. However, the semiconductor chips 20 and 30 are formed to have the same lateral width. Also, the bonding pads 2 are disposed so that all of the distances d₂₁, d₂₂, d₃₁, and d₃₂ from the left side 21 and the right side 22 of each semiconductor chip 20, and the left side 31 and the right side 32 of each semiconductor chip 30, to the left and right side of the quadrangles formed by bonding pads 2 facing each other, respectively, are identical.

On the wafer 100, a plurality of semiconductor chips of the size and type different from those of the semiconductor chips 20 and 30 are also formed. However, all the semiconductor chips formed on the wafer 100 have the same lateral width. Also, the bonding pads 2 are arranged so as to the draw same size of quadrangles, and the distances from the left and right side of the quadrangle to the left and right side of the facing semiconductor chip are identical, respectively.

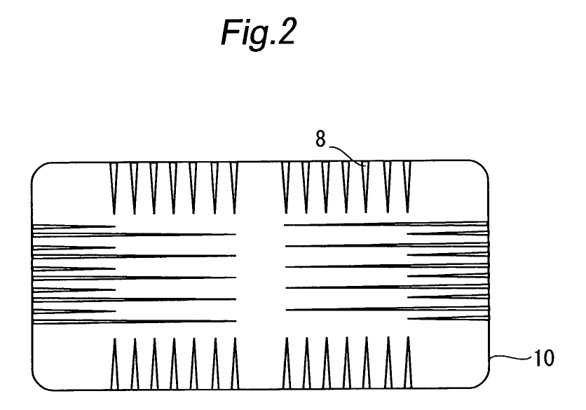

FIG. 2 is a diagram showing a probe card used in First Embodiment of the present invention.

In FIG. 2, the reference numeral 8 denotes a probe needle, and the reference numeral 10 denotes a probe card. The probe needle 8 and the probe card 10 are used in the tester for conducting the electrical test of semiconductor chips. The probe needles 8 are provided on the probe card 10. The probe card 10 is mounted on a prober (not shown). The prober is connected to the tester. Here, the prober is a device for contacting the probe needles 8 provided on the probe card 10 to the bonding pads 2. The tester is a device incorporating a computer for measuring semiconductor chips, and the tester transmits electric signals to the bonding pads 2 through the probe needles 8 to test semiconductor chips.

A probe card 10 can test two semiconductor chips at the same time. In other words, the probe needles 8 are provided in the same number as the total number of the bonding pads 2 on two semiconductor chips so as to correspond to all the bonding pads 2 on the two semiconductor chips. The probe needles 8 are disposed so that the tips thereof correspond to two quadrangles formed by the bonding pads 2.

Next, a method for testing semiconductor chips using the probe card 10 will be described.

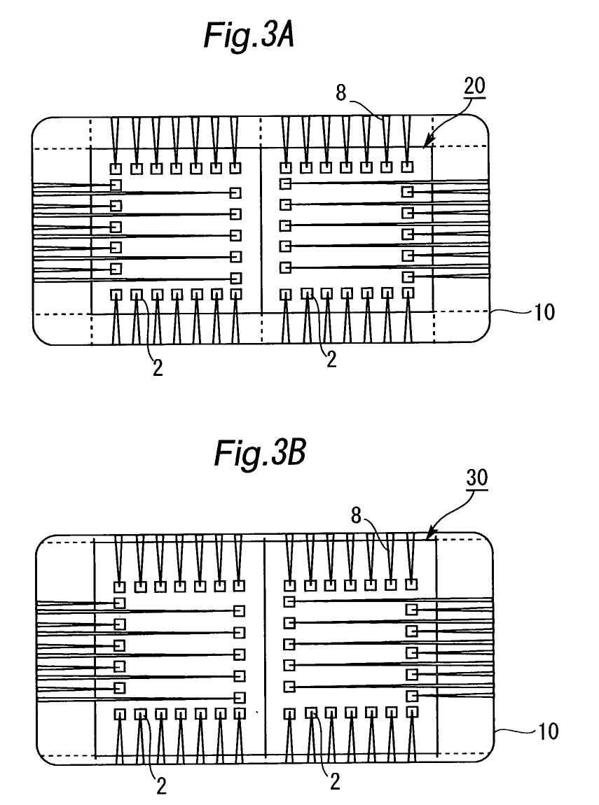

FIG. 3 is a conceptual diagram showing the state of the test of semiconductor chips using a probe card 10. FIG. 3A and FIG. 3B show the states of the tests of semiconductor chips 20 and 30, respectively.

First, a probe card 10 is mounted to the prober. The prober is connected to the tester. A wafer 100 is set on the measuring stage (not shown) of the prober.

Next, as FIG. 3A shows, each probe needle 8 on the probe card 10 is allowed to contact each bonding pad 2 formed on the surfaces of two adjoining semiconductor chips 20. In this state, the tester transmits electric signals through probe needles to the semiconductor chips 20. The signal waveforms outputted from the semiconductor chips 20 in response to the transmitted signal waveforms are read, and compared with previously programmed correct signal waveforms to determine whether the semiconductor chips 20 is acceptable or not. At this time, if a semiconductor chip 20 is not acceptable, the chip 20 is marked, or quality information is stored for the determination of the quality or the marking of defective chips in other processes.

Next, the stage (not shown) is moved to test next two semiconductor chips on the wafer 100 similarly. Thus, the test of semiconductor chips is conducted sequentially two at a time, and as FIG. 3B shows, semiconductor chips 30 are also tested.

Here, the size of a semiconductor chip 30 differs from the size of a semiconductor chip 20. However, as described above, the same number of bonding pads 2 are disposed on the semiconductor chip 30 so as to form a quadrangle of the same size as the quadrangle formed by the bonding pads 2 disposed on the semiconductor chip 20. Also, all of the distances d₂₁, d₂₂, d₃₁, and d₃₂ from the left side 21 and the right side 22 of each semiconductor chip 20, and the left side 31 and the right side 32 of each semiconductor chip 30, to the left and right side of the quadrangles formed by the bonding pads 2 facing each other, respectively, are identical. In other words, the location of the bonding pads 2 disposed on the semiconductor chip 30 corresponds to the tips of probe needles 8 of the probe card 10 used in the test of the semiconductor chip 20. Since the semiconductor chip 30 has external integrated circuit regions 6 on the upper and lower areas, the semiconductor chip 30 is larger than the semiconductor chip 20; however, as FIG. 3B shows, the same probe card 10 can be used for the continuous tests of the semiconductor chip 30.

In all the semiconductor chips on the wafer 100, the lateral width, and the number and locations of bonding pads 2 are standardized. Therefore, all the semiconductor chips formed on the wafer 100 can be tested using the same probe card 10 continuously two at a time.

Thereby, semiconductor chips can be tested using the same probe card 10 continuously two at a time. Therefore, time consumed for testing a wafer can be shortened, and increase in time for testing due to mounting of the probe card can be minimized. Also, since the preparation of probe cards corresponding to different semiconductor chips is not required, increase in production costs due to the manufacture of probe cards can be reduced.

In First Embodiment, the case where adjoining semiconductor chips are tested two at a time is described. However, the present invention is not limited to the case where two semiconductor chips are tested at the same time, but three or more semiconductor chips can also be tested at the same time. When three or more semiconductor chips are tested at the same time, the same number of bonding pads are disposed on each semiconductor chip formed on a wafer so as to form the same size of quadrangles, and the distance between the left side and the right side of a semiconductor chip, and the left side and the right side of the facing quadrangle of bonding pads, respectively are made identical; thereby, continuous testing can be conducted using the same probe card.

Here, all of the distances d₂₁, d₃₁, d₂₂, and d₃₂ from the left side 21 and the right side 22 of each semiconductor chip 20, and the left side 31 and the right side 32 of each semiconductor chip 30, to the left and right side of the quadrangles formed by the bonding pads 2 facing each other, respectively, are identical. However, the present invention is not limited thereto, but the distances d₂₁ and d₃₁ from the left side 21 and 31 of each of semiconductor chips 20 and 30 to the left side of the quadrangle formed by the bonding pads, respectively, can be made identical; and the distances d₂₂ and d₃₂ from the right side 22 and 32 of each of semiconductor chips 20 and 30 to the right side of the quadrangle formed by the bonding pads, respectively, can be made identical; but the distances d₂₁ and d₃₁ between the left sides can differ from the distances d₂₂ and d₃₂ between the right sides.

Here, First Embodiment is described using semiconductor chips 20 and 30 of different sizes formed in a wafer. However, the present invention is not limited to the case where semiconductor chips of different sizes are formed in a wafer, but, for example, semiconductor chips of the same size may be formed on a wafer, and semiconductor chips of the other sizes may be formed on other wafers.

Second Embodiment

In First Embodiment, the bonding pads 2 on each semiconductor chip are arranged so as to form the same size of quadrangle, and the distances between the left and right sides of a semiconductor chip, and the left and right sides of the facing quadrangle formed by bonding pads 2, respectively are standardized to be identical.

In Second Embodiment, all the quadrangles formed by bonding pads 2 on each semiconductor chip 20 and 30 are also made identical. However, in Second Embodiment, the distances between the facing sides of the quadrangles formed by bonding pads 2 d₂₀ and d₃₀ in the area between two semiconductor chips to be tested at the same time are made identical.

Such an arrangement is not limited to semiconductor chip 20 and 30, but it is standardized for the area between two semiconductor chips on the wafer 100 to be tested at the same time.

Since other parts are the same as in First Embodiment, description thereof will be omitted.

Thereby, the locations of the bonding pads 2 can be allowed to correspond to probe needles provided on the probe card that can test two semiconductor chips at a time. Therefore, semiconductor chips can be continuously tested two at a time using the same probe card.

According to Second Embodiment, it is sufficient to standardize quadrangles formed by bonding pads 2, and to make the distances between two facing side of the quadrangles identical in the area between two semiconductor chips to be tested at the same time. Therefore, even when semiconductor chips of different widths not only lengthwise but also laterally must be formed on the same wafer, the continuous test can be conducted using the same probe card 10.

Here, a probe card 10 for testing two adjoining semiconductor chips at the same time is described. However, the present invention is not limited to the test of two semiconductor chips, but three or more semiconductor chips may be tested at the same time. In this case, it is sufficient to standardize the all the distances between two facing sides of quadrangles formed by bonding pads 2 in the area between a plurality of semiconductor chips to be tested at the same time to correspond to the arrangement of the probe needles 8 of the probe card 10.

Third Embodiment

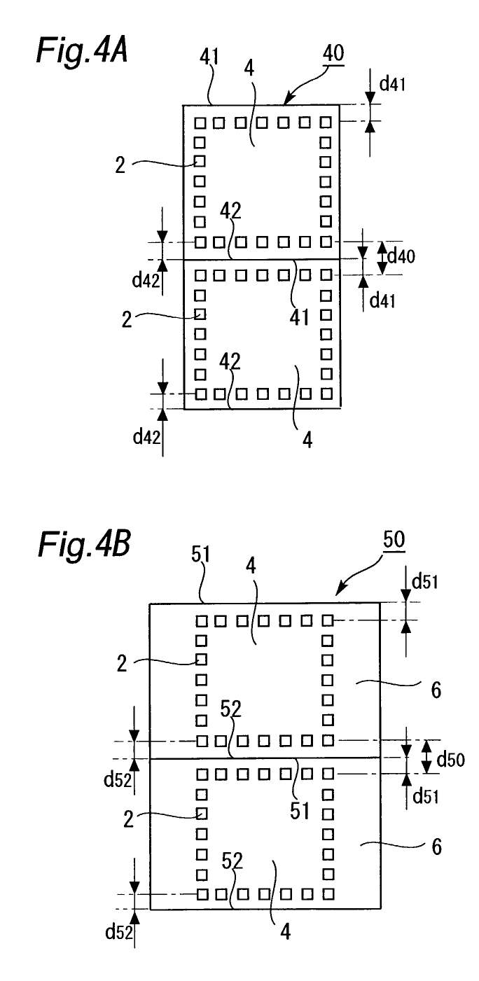

FIG. 4 is a top view showing a semiconductor chip according to Third Embodiment of the present invention.

In FIG. 4A, the reference numeral 40 denotes a semiconductor chip. FIG. 4A shows two semiconductor chips 40 of the same size vertically adjoining on a wafer.

On the surface of each semiconductor chip 40, the same number of bonding pads 2 are disposed so as to form a quadrangle of the same size. The left side and the right side of the quadrangle formed by the bonding pads 2 on a semiconductor chip 40 are disposed in line with the left side and the right side of the quadrangle formed by the bonding pads 2 on the other semiconductor chip 40, respectively. An integrated circuit region 4 is formed inside each quadrangle formed by the bonding pads 2.

In FIG. 4B, the reference numeral 50 denotes a semiconductor chip. FIG. 4B shows two semiconductor chips 50 of the same size vertically adjoining on a different location from the semiconductor chips 40 of the wafer.

On the surface of each semiconductor chip 50, the same number of bonding pads 2 are also disposed so as to form a quadrangle of the same size as in the semiconductor chips 40. The left side and the right side of the quadrangle formed by the bonding pads 2 on a semiconductor chip 50 are disposed in line with the left side and the right side of the quadrangle formed by the bonding pads 2 on the other semiconductor chip 50, respectively. External integrated circuit regions 6 are formed on the left and right areas outside each quadrangle, as well as an integrated circuit region 4 formed inside each quadrangle.

Although the lateral width of the semiconductor chip 40 differs from that of the semiconductor chip 50, their vertical widths are identical. The bonding pads 2 are disposed so that the distances d₄₁, d₅₁, d₄₂, and d₅₂ between the upper side and the lower side of the quadrangle, and the upper side 41, 51 and the lower side 42, 52 of the semiconductor chips 40 and 50, respectively, are identical. Furthermore, the left and right sides of the quadrangles on two semiconductor chips to be tested at the same time are disposed in line, respectively.

Thereby, the continuous test can be conducted by using a probe card for testing two vertically adjoining semiconductor chips at the same time.

Since other parts are the same as in First or Second Embodiment, the description thereof will be omitted.

Here, the locations of bonding pads are standardized by equalizing all the distances between the upper and lower sides of semiconductor chips, and the upper and lower sides of the quadrangles formed by bonding pads. However, as in Second Embodiment, distances d₄₀ and d₅₀ between quadrangles formed by bonding pads 2 facing in the area between semiconductor chips to be tested at the same time may be standardized.

Here, the case where two semiconductor chips are tested at the same time is described. However, the present invention is not limited to two, but three or more semiconductor chips can be tested at the same time. In this case also, it is sufficient to standardize the size of quadrangles formed by bonding pads, and the distances between the upper and lower sides of the quadrangles, and the upper and lower sides of the semiconductor chips facing thereto, or the distances between two sides of the quadrangles facing in the area between semiconductor chips.

In First and Second Embodiments, the case where laterally adjoining semiconductor chips in line are tested was described, and in Third Embodiment, the case where vertically adjoining semiconductor chips in line are tested was described. However, the present invention is not limited to the cases where laterally or vertically adjoining semiconductor chips in line in the same direction are tested at the same time, but a plurality of semiconductor chips vertically and laterally adjoining can also be tested at the same time. In this case also, it is sufficient to standardize the vertical and lateral locations of bonding pads.

Fourth Embodiment

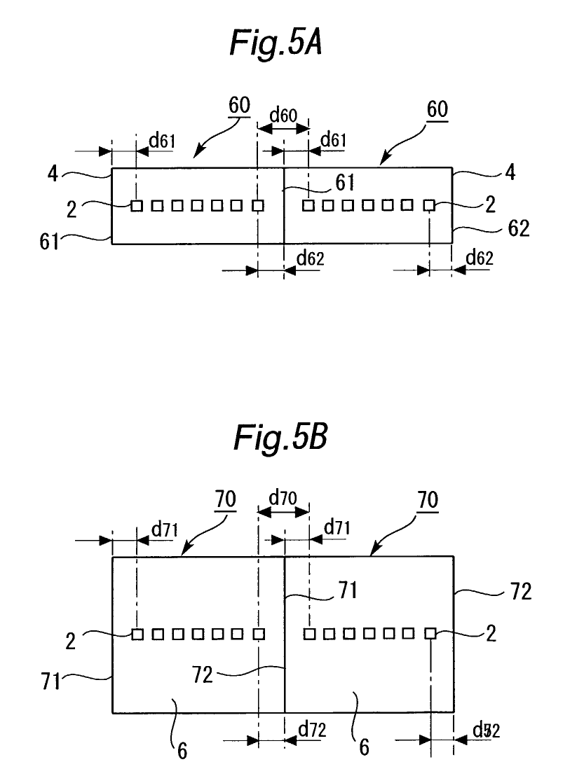

FIG. 5 is a diagram showing semiconductor chips to be tested according to Fourth Embodiment of the present invention.

In FIG. 5A, the reference numeral 60 denotes a semiconductor chip. FIG. 5A shows two adjoining semiconductor chips 60 of the same size. In Fourth Embodiment, the same number of bonding pads 2 are linearly disposed on the same locations of each semiconductor chip 60.

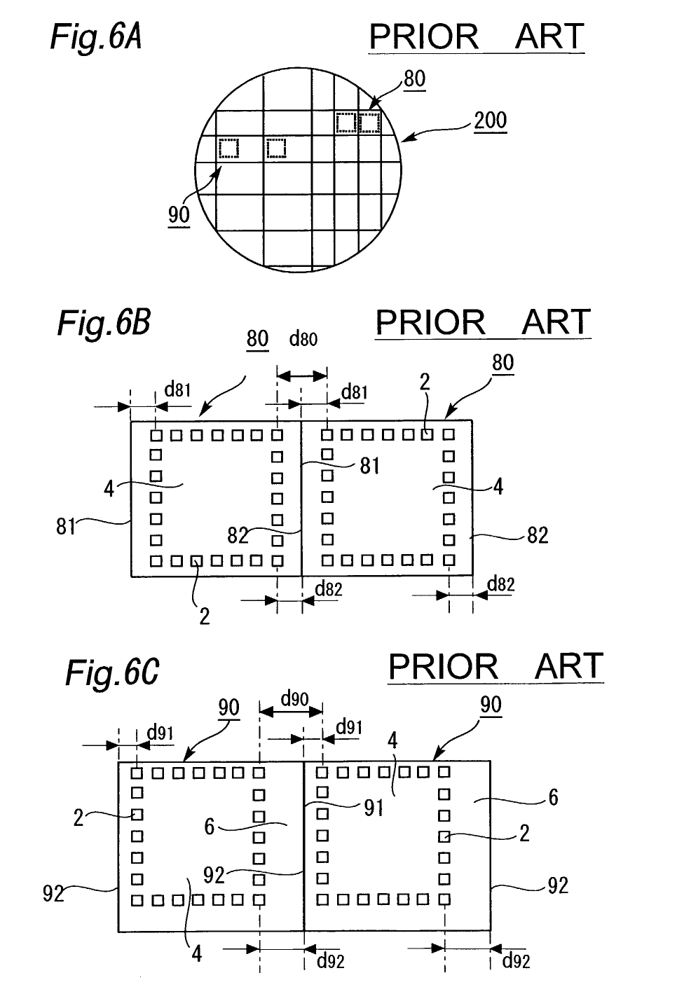

In FIG. 5B, the reference numeral 70 denotes a semiconductor chip. FIG. 6B shows two adjoining semiconductor chips 70 of the same size. The same number of bonding pads 2 are also disposed on each semiconductor chip 70 in line in the same distance as the semiconductor chip 60.

Distances d₆₁ and d₆₂ between the left side 61 and the right side 62 of the semiconductor chip 60, and the leftmost and the rightmost bonding pads 2, respectively; and distance d₇₁ and d₇₂ between the left side 71 and the right side 72 of the semiconductor chip 70, and the leftmost and the rightmost bonding pads 2 facing thereto, respectively are all identical.

Since other parts are the same as in First to Third Embodiments, the description thereof will be omitted.

As described above, when the distance between arrangements, and the number of bonding pads are identical in semiconductor chips 60 and 70, and the distances between the left and right sides of the semiconductor chip and the bonding pads are identical, the semiconductor chips can be tested continuously two at a time using a probe card corresponding thereto.

Here, the case where the distances between left and right sides and the leftmost and right most bonding pads are standardized, and the bonding pads are arranged in a line was described. However, the present invention is not limited thereto, but it is sufficient to dispose bonding pads 2 so as to correspond to probe needles used for testing, for example, by standardizing the distances d₆₀ and d₇₀ between the leftmost bonding pad and the rightmost bonding pad facing in the area between two semiconductor chips.

Also, the case where the bonding pads 2 are arranged in a line was described. However, the present invention is not limited thereto, but it is sufficient to dispose bonding pads on each semiconductor chip so as to correspond to probe needles used for testing.

In the present invention, “a predetermined side of a semiconductor chip” and “a side facing the predetermined side” mean two circumferential sides facing each other of a semiconductor chip, and for example, the relationship when the predetermined side is the left side as in First, Second, and Fourth Embodiments, the facing side is the right side. Or as the relationship in Third Embodiment, when the predetermined side is the upper side, the facing side is the lower side.

In the present invention, the specific patterns on which electrodes are disposed include, for example, quadrangles formed by bonding pads as in First to Third Embodiments, or straight lines as in Fourth Embodiment.

Also, in the present invention, the case where the distances between a predetermined side and the other side of a semiconductor chip and electrodes become a specific distance is the relationship in which, for example, all the distances d₂₁ and d₃₁ between the left sides 21 and 31 of a plurality of semiconductor chips, and the bonding pads; and all the distances d₂₂ and d₃₂ between the right sides 22 and 32 of a plurality of semiconductor chips, and the bonding pads are identical. Here, since all the patterns of disposing bonding pads are standardized, when the distances to the left sides and the right sides of the quadrangles formed by the bonding pads are constant, the distances between the bonding pads disposed on other locations and the left sides and the right sides are also constant.

Furthermore, in the present invention, a plurality of semiconductor chips adjoining in a predetermined area include, for example, two semiconductor chips tested by a probe card in Second Embodiment.

Also, the distances between facing electrodes in the area between the semiconductor chips include, for example, as FIGS. 1B and C show, the distances d₂₀ and d₃₀ between two facing sides of quadrangles formed by the bonding pads in Second Embodiment.

In addition, that the distance between electrodes becomes a predetermined distance means the relationship in which, for example, the distances d₂₀ and d₃₀ becomes identical.

The features and the advantages of the present invention as described above may be summarized as follows.

According to one aspect of the present invention, as described above, in a plurality of semiconductor chips to be tested at the same time, electrodes are disposed on the surface of each semiconductor chip so as to form an identical pattern. Also, distances between each electrode, and the left and right side, or the upper and lower sides of the semiconductor chip are made identical.

Accordingly, continuous tests can be conducted using a probe card that can test a plurality of semiconductor chips at the same time, also for other semiconductor chips. Therefore, no changes of the probe card to meet the different size of semiconductor chips during the test are required. Thus, time consumed by the test can be shortened. Also, there is no need to manufacture probe cards to meet each semiconductor chip. Thus, increase in production costs due to the manufacture of probe cards can be prevented.

In another aspect, in a plurality of semiconductor chips to be tested at the same time, electrodes are disposed so as to form the same pattern of the surface of each semiconductor chip, and the distances between facing electrodes are made identical in the area between the semiconductor chips to be tested at the same time.

Accordingly, continuous tests can also be conducted using a probe card that can test a plurality of semiconductor chips at the same time, also for other semiconductor chips. Therefore, increase in time for testing, and increase in production costs can be minimized.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-377470, filed on December, 2001 including specification, claims, drawings and summary, on which the Convention priority of the present application is based, are incorporated herein by reference in its entirety.

1. A plurality of semiconductor chips, each comprising:
a plurality of electrodes for electrical connection to outside, wherein:
said electrodes are disposed on a surface of each of said semiconductor chips in a predetermined pattern; and
a distance between a predetermined side of each of said semiconductor chips and each of said electrodes, and a distance between a side that faces said predetermined side of each of said semiconductor chips and each of said electrodes are predetermined distances, respectively.

2. The semiconductor chips according to claim 1, wherein:
said predetermined side is a left side of each of said semiconductor chips, and
the side that faces said predetermined side is a right side of each of said semiconductor chips.

3. The semiconductor chips according to claim 1, wherein:
said predetermined side is a upper side of each of said semiconductor chips, and
the side that faces said predetermined side is a lower side of each of said semiconductor chips.

4. The semiconductor chips according to claim 1, wherein said electrodes are disposed on the surface of each of said semiconductor chips so as to form a predetermined quadrangle pattern.

5. A plurality of semiconductor chips, each comprising:
a plurality of electrodes for electrical connection to outside, wherein:
said electrodes are disposed on a surface of each of said semiconductor chips in a predetermined pattern; and
in a relation between said semiconductor chips adjacent to each other at a predetermined location, a distance between said electrodes facing each other is a predetermined distance.

6. The semiconductor chips according to claim 5, wherein said electrodes are disposed on the surface of each of said semiconductor chips so as to form a predetermined quadrangle pattern.
